(19) United States
(12) Patent Application Publication
(10) Pub. No.: US 2024/0380181 A1
(43) Pub. Date: Nov. 14, 2024

(54) SEMICONDUCTOR DEVICE AND MANUFACTURING METHOD THEREFOR

(71) Applicant: Nippon Telegraph and Telephone Corporation, Tokyo (JP)

(72) Inventors: Wataru Kobayashi, Tokyo (JP); Manabu Mitsuhara, Tokyo (JP); Shigeru Kanazawa, Tokyo (JP); Takahiko Shindo, Tokyo (JP)

(21) Appl. No.: 18/689,135

(22) PCT Filed: Oct. 8, 2021
(86) PCT No.: PCT/JP2021/037313

§ 371 Date: Mar. 5, 2024

(51) Int. Cl. H01S 5/223

(52) U.S. Cl. CPC H01S 5/223

(57) ABSTRACT

In an embodiment semiconductor device, a first optical element, a second optical element, and an optical waveguide for optically connecting the first optical element and the second optical element are provided on a substrate including a semi-insulating compound semiconductor. The first optical element is formed in a first element region of the substrate. The second optical element is formed in a second element region of the substrate. The optical waveguide is formed in a separation region between the first element region and the second element region of the substrate. The optical waveguide is configured by a cladding including a semi-insulating compound semiconductor on the substrate and a core including a compound semiconductor buried in the cladding.

### CROSS-REFERENCE TO RELATED APPLICATIONS

This application is a national phase entry of PCT Application No. PCT/JP2021/037313, filed on Oct. 8, 2021, which application is hereby incorporated herein by reference.

### TECHNICAL FIELD

The present invention relates to a semiconductor device and a method for producing the same.

### BACKGROUND

With the use of cloud technology and diversification of IP services such as online business, communication traffic has been increasing. In order to meet these requirements, optical communication devices supporting communication traffic have been more developed than ever in the past to improve performance such as large capacity, low power consumption, and miniaturization and high density of modules.

Optical communication devices to be used are classified because transmission distances are different according to applications in optical communications. In an application of 10 km or less, such as between racks of data centers and between centers, a device in which a direct modulation laser (DML) and an electro-absorption (EA) optical modulator integrated laser are monolithically integrated in the same substrate is used. The EA optical modulator integrated laser is used even in communication for access whose transmission distance is 80 km or less.

The basic configuration of such a monolithically integrated device has a semiconductor laser that produces light as a carrier wave, an EA optical modulator for modulating the carrier wave, and an optical amplifier for amplifying the intensity of the modulated light. A conventional monolithically integrated device is fabricated using a conductive substrate (mainly an n-polar InP substrate). Therefore, the potential of the substrate polarity cannot be changed for each integrated device and becomes common. In driving the optical modulator, a method of driving with a single-phase modulation signal under such a restriction has been used.

In the integration technique of the conventional semiconductor device, a conductive substrate is mainly used, and each functional part (optical element) is integrated using the potential of the conductive substrate as a common potential. In this configuration, since one of the two conductive polarities (p-polarity, n-polarity) of the semiconductor device is operated as a common potential, it is impossible to realize differential modulation driving of the optical modulator. Here, this point will be described in detail.

FIG. 3 shows a configuration of the conventional monolithically integrated element. A first active layer 302 of a first functional part 321, a second active layer 303 of a second functional part 322, a high-resistance p-polar layer 305, a low-resistance first p-polar layer 306, and a low-resistance second p-polar layer 307 are provided on an n-polar semiconductor substrate 301. Further, in an electric separation part 323, a core 304 is provided on the semiconductor substrate 301. In the electric separation part 323, the p-polar layer 305 around the core 304 is used as a cladding to constitute an optical waveguide. By removing the low-resistance p-polar layer of the electric separation part 323, electric separation of the p-polar side of the first functional part 321 and the second functional part 322 is achieved.

However, since the n-polar side is connected via the semiconductor substrate 301, the first functional part 321 and the second functional part 322 cannot be electrically separated from each other. Differential modulation driving for modulating the potentials of the p-polarity and the n-polarity cannot be realized by this configuration.

However, in order to maximize the performance of the optical modulator, it is desirable to realize the differential modulation drive. This is because the differential modulation drive can achieve improvement in the use efficiency of the modulation voltage and improvement in the S/N ratio of the optical waveform by suppressing common mode noise.

### SUMMARY

### Technical Problem

In order to realize the differential modulation drive, a technique for producing a device on a semi-insulating (SI) substrate can be considered. However, this configuration has the following problems. In FIGS. 4A, 4B, 4C, 4D, and 4E, the problem in performing electrode separation on an SI substrate 401 by the butt joint process is shown. Although the butt joint process forms different semiconductor layers on the same substrate, there is a problem in which the flatness of the semiconductor layers is impaired, as described below.

As shown in FIGS. 4A, 4B, and 4C, a p-type semiconductor layer 411 is formed on the SI substrate 401, a first p-type semiconductor layer 402 and a second p-type semiconductor layer 403 are formed by separating the p-type semiconductor layer 411, and an SI semiconductor layer 404 is grown between them. When the SI semiconductor layer 404 different from the first p-type semiconductor layer 402 and the second p-type semiconductor layer 403 is crystal-grown, the flatness of the SI semiconductor layer 404 near the connection part is impaired. An active layer is grown on these layers, but if the active layer is grown in a state where the flatness of the lower layer of the active layer is impaired, the flatness of the active layer grown on the upper layer is also impaired, and the in-plane uniformity is deteriorated. A deterioration of the crystal quality of the active layer (deterioration of PL intensity and shift of band gap wavelength) also occurs. When the active layer is considered as an optical waveguide, waveguide loss occurs.

Further, it is considered a case in which, as shown in FIGS. 4D and 4E, a p-type semiconductor layer 411 is formed on the SI substrate 401, an active layer 415 is formed on the p-type semiconductor layer 411, and these are separated to form the first p-type semiconductor layer 402, the second p-type semiconductor layer 403, the first active layer 412, and the second active layer 413, and the SI semiconductor layer 404 and a core 414 are grown therebetween. In this way, when the two upper and lower layers are butt joined together at once, a problem of height deviation between the active layer of the functional part and the core of the electrical separation part is caused, thereby a waveguide loss is caused.

Embodiments of the present invention have been made to solve the above problems, and have an object to realize electrical separation between two optical elements without causing waveguide loss between the two optical elements.

### Solution to Problem

A semiconductor device according to embodiments of the present invention includes a substrate including a semi-insulating compound semiconductor; a waveguide type first optical element formed in a first element region of the substrate; a waveguide type second optical element formed in a second element region of the substrate; and an optical waveguide formed in a separation region between the first element region and the second element region of the substrate, for optically connecting the first optical element and the second optical element, in which the first optical element includes a first semiconductor layer including a compound semiconductor of a first conductivity type that is formed on the substrate; a first active layer including a compound semiconductor that is formed on the first semiconductor layer; and a second semiconductor layer including a compound semiconductor of a second conductivity type that is formed on the first active layer, the second optical element includes a third semiconductor layer including a compound semiconductor of a first conductivity type that is formed on the substrate; a second active layer including a compound semiconductor that is formed on the third semiconductor layer; and a fourth semiconductor layer including a compound semiconductor of a second conductivity type that is formed on the second active layer, and the optical waveguide includes a cladding including a semi-insulating compound semiconductor that is formed on the substrate; and a core including a compound semiconductor buried in the cladding.

Further, a method of manufacturing a semiconductor device according to embodiments of the present invention is a method for manufacturing a semiconductor device which includes a substrate including a semi-insulating compound semiconductor; a waveguide type first optical element formed in a first element region of the substrate; a waveguide type second optical element formed in a second element region of the substrate; and an optical waveguide formed in a separation region between the first element region and the second element region of the substrate, for optically connecting the first optical element and the second optical element. The method includes: a first step of forming a first conductivity type layer including a compound semiconductor of a first conductivity type on the substrate; a second step of forming an active layer including a compound semiconductor in the first element region and the second element region on the first conductivity type layer, and forming a core layer including a compound semiconductor in the separation region on the first conductivity type layer; a third step of forming a second conductivity type layer including a compound semiconductor of a second conductivity type on the active layer and the core layer; a fourth step of etching the second conductivity type layer, the active layer, and the core layer so as to penetrate in the thickness direction, etching the first conductivity type layer so as to reach up to the middle to process it into a ridge shape, forming the first optical element including a first semiconductor layer including a compound semiconductor of a first conductivity type, a first active layer including a compound semiconductor that is formed on the first semiconductor layer, and a second semiconductor layer including a compound semiconductor of a second conductivity type that is formed on the first active layer in the first element region, forming the second optical element including a third semiconductor layer including a compound semiconductor of a first conductivity type, a second active layer including a compound semiconductor that is formed on the third semiconductor layer, a fourth semiconductor layer including a compound semiconductor of a second conductivity type that is formed on the second active layer in the second element region, and forming a core including a compound semiconductor in the separation region; a fifth step of removing the second conductivity type layer and the first conductivity type layer of the separation region, and a sixth step of forming a cladding including a semi-insulating compound semiconductor that buries the core of the separation region to form the optical waveguide.

### Advantageous Effects of Embodiments of the Invention

As described above, according to embodiments of the present invention, since the first optical element and the second optical element are formed on the substrate including the semi-insulating compound semiconductor, and the cladding of the optical waveguide connecting them includes the semi-insulating compound semiconductor, the electric separation between the two optical elements can be realized without causing waveguide loss between the two optical elements.

### BRIEF DESCRIPTION OF THE DRAWINGS

FIG. 1A is a cross-sectional view showing a configuration of a semiconductor device according to an embodiment of the present invention.

FIG. 1B is a cross-sectional view showing a configuration of a semiconductor device according to an embodiment of the present invention.

FIG. 1C is a cross-sectional view showing a configuration of a semiconductor device according to an embodiment of the present invention.

FIG. 2A is a cross-sectional view showing the state of the semiconductor device in an intermediate step for illustrating a method for producing a semiconductor device according to an embodiment of the present invention.

FIG. 2B is a cross-sectional view showing the state of the semiconductor device in an intermediate step for illustrating the method for producing a semiconductor device according to an embodiment of the present invention.

FIG. 2C is a cross-sectional view showing the state of the semiconductor device in an intermediate step for illustrating the method for producing a semiconductor device according to an embodiment of the present invention.

FIG. 2D is a cross-sectional view showing the state of the semiconductor device in an intermediate step for illustrating the method for producing a semiconductor device according to an embodiment of the present invention.

FIG. 2E is a cross-sectional view showing the state of the semiconductor device in an intermediate step for illustrating the method for producing a semiconductor device according to an embodiment of the present invention.

FIG. 2F is a cross-sectional view showing the state of the semiconductor device in an intermediate step for illustrating the method for producing a semiconductor device according to an embodiment of the present invention.

FIG. 2G is a cross-sectional view showing the state of the semiconductor device in an intermediate step for illustrating the method for producing a semiconductor device according to an embodiment of the present invention.

FIG. 2H is a cross-sectional view showing the state of the semiconductor device in an intermediate step for illustrating the method for producing a semiconductor device according to an embodiment of the present invention.

FIG. 2I is a cross-sectional view showing the state of the semiconductor device in an intermediate step for illustrating the method for producing a semiconductor device according to an embodiment of the present invention.

FIG. 2J is a cross-sectional view showing the state of the semiconductor device in an intermediate step for illustrating the method for producing a semiconductor device according to an embodiment of the present invention.

FIG. 2K is a cross-sectional view showing the state of the semiconductor device in an intermediate step for illustrating the method for producing a semiconductor device according to an embodiment of the present invention.

FIG. 2L is a cross-sectional view showing the state of the semiconductor device in an intermediate step for illustrating the method for producing a semiconductor device according to an embodiment of the present invention.

FIG. 2M is a cross-sectional view showing the state of the semiconductor device in an intermediate step for illustrating the method for producing a semiconductor device according to an embodiment of the present invention.

FIG. 3 is a cross-sectional view showing a configuration of a semiconductor device.

FIG. 4A is a cross-sectional view showing a state of a semiconductor device in an intermediate step for illustrating a method for producing a semiconductor device.

FIG. 4B is a cross-sectional view showing a state of a semiconductor device in an intermediate step for illustrating a method for producing a semiconductor device.

FIG. 4C is a cross-sectional view showing a state of a semiconductor device in an intermediate step for illustrating a method for producing a semiconductor device.

FIG. 4D is a cross-sectional view showing a state of a semiconductor device in an intermediate step for illustrating a method for producing a semiconductor device.

FIG. 4E is a cross-sectional view showing a state of a semiconductor device in an intermediate step for illustrating a method for producing a semiconductor device.

### DETAILED DESCRIPTION OF ILLUSTRATIVE EMBODIMENTS

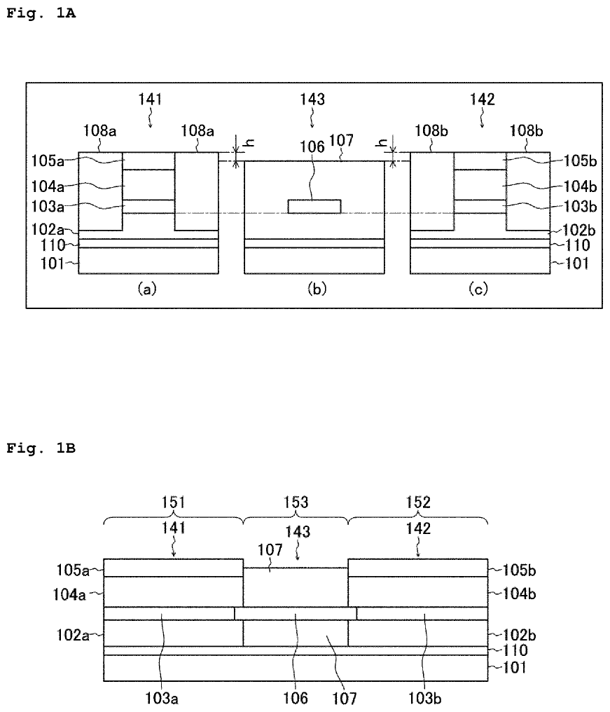

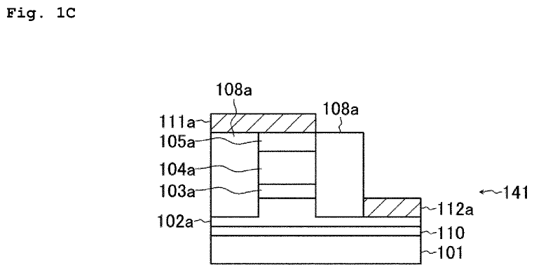

Hereinafter, a semiconductor device according to an embodiment of the present invention will be described with reference to FIGS. 1A, 1B, and 1C. By the way, FIGS. 1A and 1C show cross-sections of a plane perpendicular to a waveguide direction. Further, FIG. 1B shows a cross-section of a plane parallel to a wave guiding direction.

The semiconductor device includes: a substrate 101 including a semi-insulating compound semiconductor; a waveguide type first optical element 141; a waveguide type second optical element 142; and an optical waveguide 143 for optically connecting the first optical element 141 and the second optical element 142. The first optical element 141 is formed in a first element region 151 of the substrate 101. The second optical element 142 is formed in a second element region 152 of the substrate 101. The optical waveguide 143 is formed in a separation region 153 between the first element region 151 and the second element region 152 of the substrate 101.

Further, the first optical element 141 includes a first semiconductor layer 102a including a compound semiconductor of a first conductivity type that is formed on the substrate 101, a first active layer 103a including a compound semiconductor that is formed on the first semiconductor layer 102a, and a second semiconductor layer 104a including a compound semiconductor of a second conductivity type that is formed on the first active layer 103a.

Similarly, the second optical element 142 includes a third semiconductor layer 102b including a compound semiconductor of the first conductivity type that is formed on the substrate 101, a second active layer 103b including a compound semiconductor that is formed on the third semiconductor layer 102b, and a fourth semiconductor layer 104b including a compound semiconductor of the second conductivity type that is formed on the second active layer 103b.

Further, the optical waveguide 143 is configured by a cladding 107 including a semi-insulating compound semiconductor that is formed on the substrate 101, and a core 106 including a compound semiconductor buried in the cladding 107. For example, the first active layer 103a, the core 106, and the second active layer 103b are arranged at the same height of the bottom surfaces (lower surfaces).

Here, in the embodiment, a fifth semiconductor layer 110 including a semi-insulating compound semiconductor is provided on the substrate 101, and each layer described above is formed on the fifth semiconductor layer 110. Further, a sixth semiconductor layer 105a including a compound semiconductor of the second conductivity type into which an impurity is introduced at a higher concentration is formed on the second semiconductor layer 104a. Further, a seventh semiconductor layer 105b including a compound semiconductor of the second conductivity type into which an impurity is introduced at a higher concentration is formed on the fourth semiconductor layer 104b.

In the first optical element 141, each cross-sectional shape perpendicular to the waveguide direction of the sixth semiconductor layer 105a, the second semiconductor layer 104a, the first active layer 103a, and the first semiconductor layer 102a is formed in a ridge shape. This ridge is formed up to the middle of the first semiconductor layer 102a in the thickness direction. A lower layer part of the second semiconductor layer 104a extending to the side of the ridge should become an area where an n-electrode is formed, as described later.

Similarly, in the second optical element 142, each cross-sectional shape perpendicular to the waveguide direction of the seventh semiconductor layer 105b, the fourth semiconductor layer 104b, the second active layer 103b, and the third semiconductor layer 102b is formed in a ridge shape. This ridge is formed up to the middle of the third semiconductor layer 102b in the thickness direction. A lower layer part of the third semiconductor layer 102b extending to the side of the ridge should become an area where an n-electrode is formed.

Further, in this example, a first buried layer 108a including a semi-insulating compound semiconductor and a second buried layer 108b including a semi-insulating compound semiconductor are provided. The first buried layer 108a is formed so as to bury the side of the waveguide direction of the first optical element 141. Similarly, the second buried layer 108b is formed so as to bury the side of the waveguide direction of the second optical element 142.

Here, an upper surface of the optical waveguide 143 is formed lower than upper surfaces of the first buried layer 108a and the second buried layer 108b. The height difference between the optical waveguide 143 and the first buried layer 108a and the second buried layer 108b should be, for example, h. The difference h corresponds to the thickness of the lower layer part of the second semiconductor layer 104a and the lower layer part of the third semiconductor layer 102b, for example, where the n-electrode is formed. Further, the first buried layer 108a, the second buried layer 108b, and the cladding 107 can include the same compound semiconductor and can be continuously and integrally formed in the waveguide direction.

The substrate 101 can include, for example, semi-insulating InP. The fifth semiconductor layer 110 can include, for example, semi-insulating InGaAsP or semi-insulating InGaAs. The first semiconductor layer 102a and the third semiconductor layer 102b can include, for example, n-type InP. Further, the second semiconductor layer 104a and the fourth semiconductor layer 104b can include, for example, p-type InP. In this case, the first conductivity type is an n-type, and the second conductivity type is a p-type.

The first active layer 103a and the second active layer 103b can include, for example, InGaAsP, InGaAs, InGaAlAs or the like. Further, the core 106 can include InGaAsP, InGaAs or the like.

The first buried layer 108a and the second buried layer 108b can include, for example, semi-insulating InP. Further, the cladding 107 can include, for example, semi-insulating InP.

Further, the first optical element 141 can include, as shown in FIG. 1C, a first p-electrode 111a formed on the sixth semiconductor layer 105a and ohmic-connected to the sixth semiconductor layer 105a. The sixth semiconductor layer 105a functions as a contact layer. Further, a first n-electrode 112a which is ohmic-connected to the upper surface of the first semiconductor layer 102a can be provided on the side of the first buried layer 108a. Although not shown, the same applies to the second optical element 142.

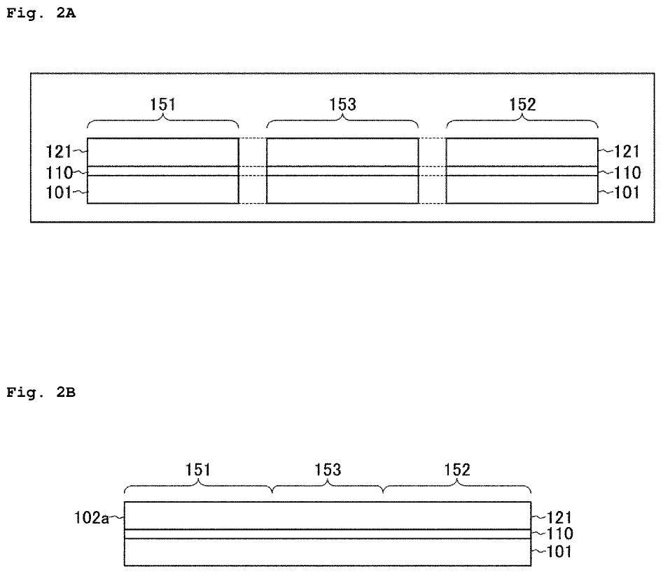

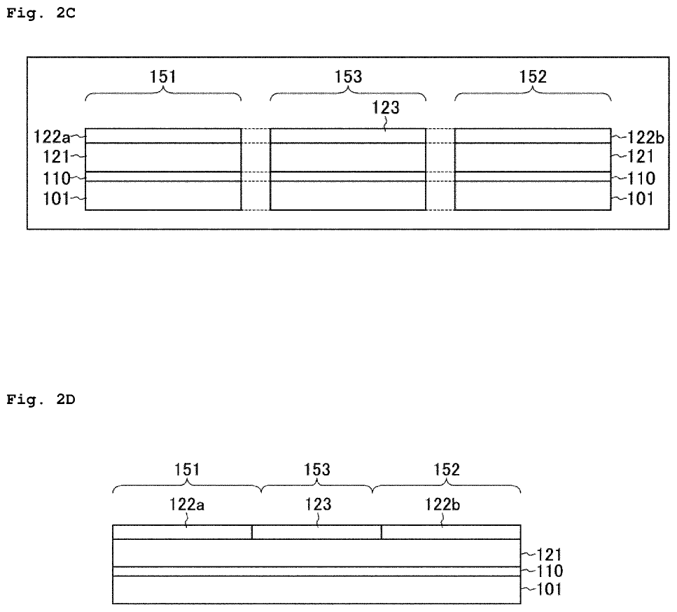

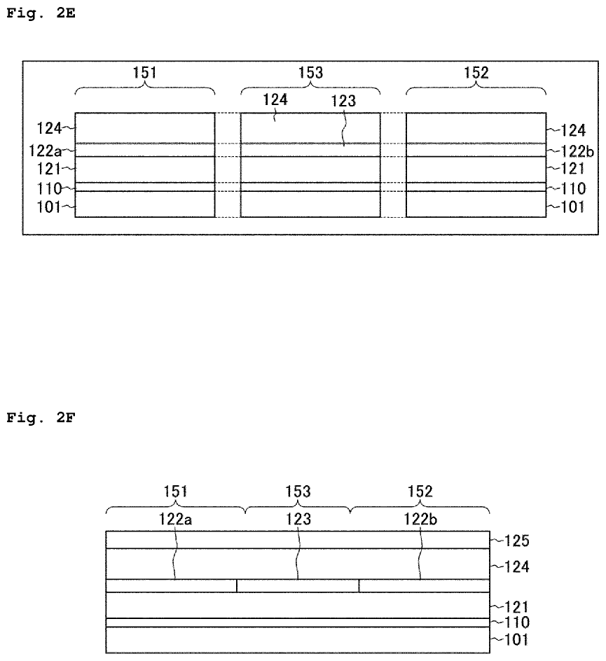

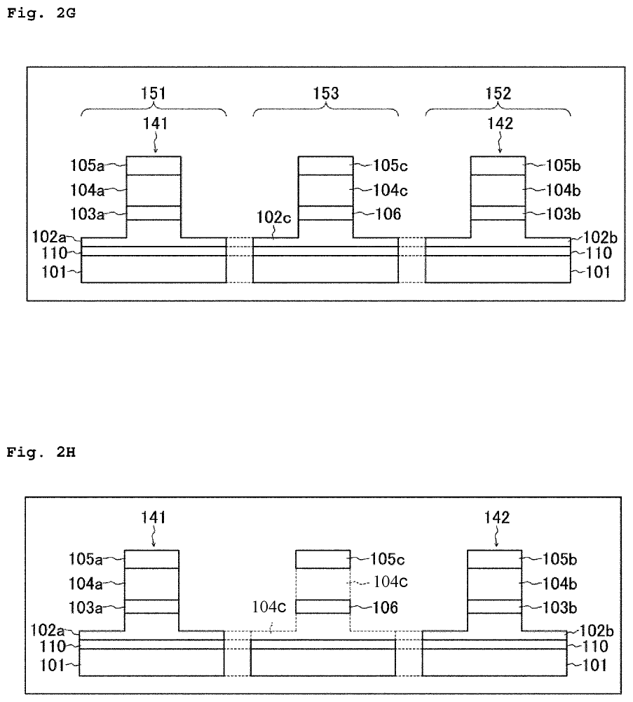

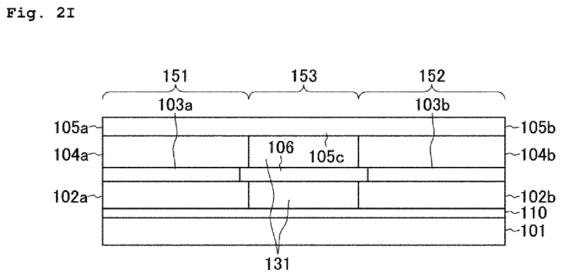

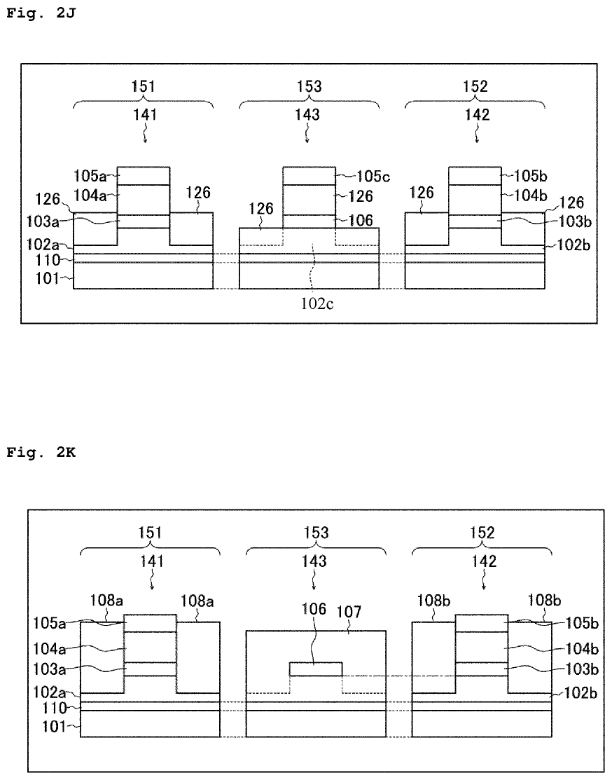

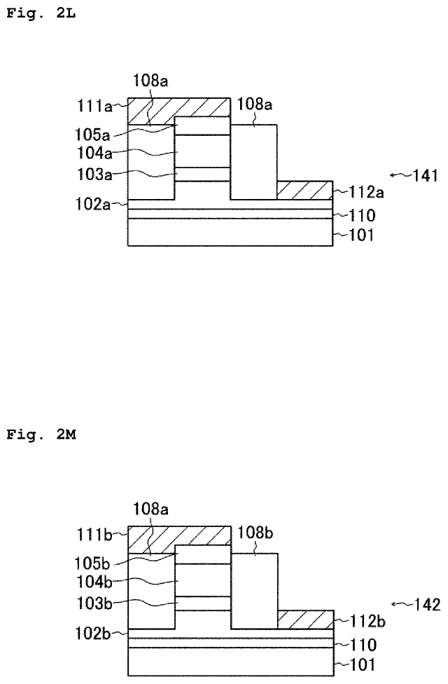

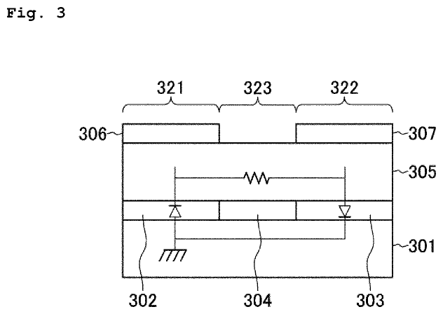

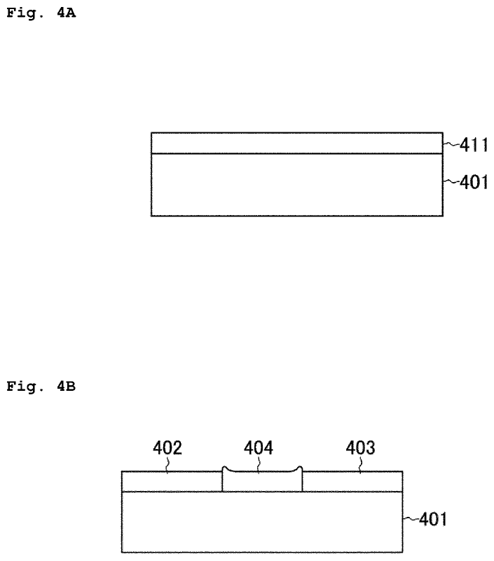

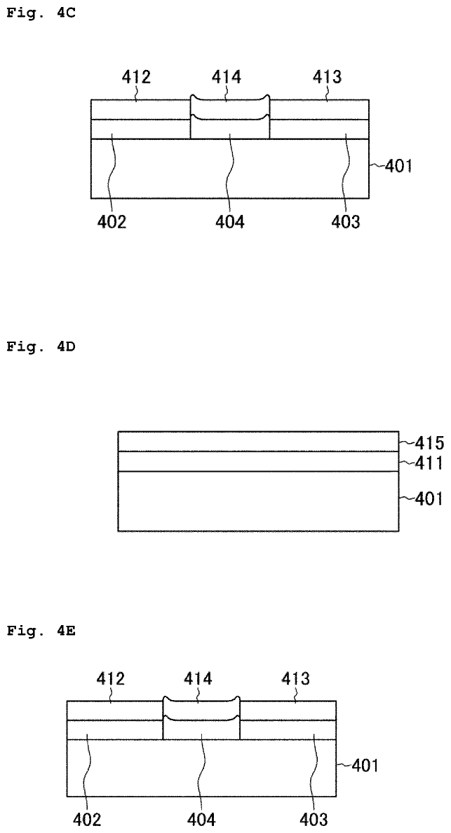

Next, a method for producing a semiconductor device according to an embodiment of the present invention will be described with reference to FIGS. 2A to 2M. This method for producing is the method for producing the semiconductor device, described above, including the first optical element 141, the second optical element 142, and the optical waveguide 143 on the substrate 101. By the way, FIGS. 2A, 2C, 2E, 2G, 2H, 2J, 2K, 2L, and 2M show a cross-section of a plane perpendicular to a waveguide direction. Further, FIGS. 2B, 2D, 2F, 2I show a cross-section of a plane parallel to a wave guiding direction.

First, as shown in FIGS. 2A and 2B, the fifth semiconductor layer 110 include, for example, a semi-insulating compound semiconductor is formed on the entire region of the substrate 101 (crystal growth) including a first element region 151, a second element region 152, and a separation region 153. Subsequently, a first conductivity type layer 121 including a compound semiconductor of a first conductivity type is formed on the fifth semiconductor layer 110 (crystal growth) (first step). The fifth semiconductor layer 110 can include, for example, undoped InGaAsP (band gap wavelength 1.1 μm). Further, the first conductivity type layer 121 can include n-InP doped with Si as an n-type impurity (Si doping amount 1E18 [cm⁻³]), for example.

Next, as shown in FIGS. 2C and 2D, an active layer 122a for forming a semiconductor laser is formed on the first conductivity type layer 121 of the first element region 151. The active layer 122a can include, for example, InGaAsP. Further, an active layer 122b for forming an EA optical modulator is formed on the first conductivity type layer 121 of the second element region 152. The active layer 122b can include, for example, InGaAlAs. Further, a core layer 123 is formed on the first conductivity type layer 121 of the separation region 153. The core layer 123 can include InGaAsP. The active layer 122a, the core layer 123, and the active layer 12b can be formed in this order using a so-called butt joint process (second step). The length of the active layer 122a (active layer 122b) in the waveguide direction and the length of the core layer 123 in the waveguide direction can be freely determined. For example, the length of the active layer 122a (active layer 122b) in the waveguide direction can be 300 μm, and the length of the core layer 123 in the waveguide direction can be 200 μm.

Next, as shown in FIG. 2E, a second conductivity type layer 124 including a compound semiconductor of a second conductivity type is formed on the active layer 122a, the active layer 122b, and the core layer 123 (crystal growth) (third step). The second conductivity type layer 124 can include, for example, p-InP doped with Zn as p-type impurity (Zn doping amount 1E18 [cm⁻³]).

Subsequently, as shown in FIG. 2F, a semiconductor layer 125 including a compound semiconductor of the second conductivity type is formed on the second conductivity type layer 124 (crystal growth). The semiconductor layer 125 can include, for example, p-type InGaAsP or p-type InGaAs.

Next, the semiconductor layer 125, the second conductivity type layer 124, the active layer 122a, the active layer 12b, and the core layer 123 are etched so as to penetrate in the thickness direction, and the first conductivity type layer 121 is etched so as to reach the middle to process it into a ridge shape, as shown in FIG. 2G, so that a first optical element 141 is formed in the first element region 151, a second optical element 142 is formed in the second element region 152, and a core 106 is formed in the separation region 153 (fourth step). Here, processing the ridge shape described above is performed by stopping the etching in the middle of the first conductivity type layer 121. With this processing, the second semiconductor layer 104a and the fourth semiconductor layer 104b are formed in a core shape having the same waveguide direction.

The first optical element 141 includes a first semiconductor layer 102a including a compound semiconductor of a first conductivity type, a first active layer 103a including a compound semiconductor that is formed on the first semiconductor layer 102a, and a second semiconductor layer 104a including a compound semiconductor of a second conductivity type that is formed on the first active layer 103a. The second optical element 142 includes a third semiconductor layer 102b including the compound semiconductor of the first conductivity type, a second active layer 103b including a compound semiconductor that is formed on the third semiconductor layer 102b, and a fourth semiconductor layer 104b including the compound semiconductor of the second conductivity type that is formed on the second active layer 103b.

Further, in this stage, the core 106 is formed on a first conductivity type layer 102c continuing to the first semiconductor layer 102a and the third semiconductor layer 102b in the separation region 153. Further, a second conductivity type layer 104c continuing to the second semiconductor layer 104a and the fourth semiconductor layer 104b is formed on the core 106, on which a semiconductor layer 105c continuing to a sixth semiconductor layer 105a and a seventh semiconductor layer 105b is formed.

Next, the second conductivity type layer 104c and the first conductivity type layer 102c of the separation region 153 are removed, and as shown in FIGS. 2H and 2I, peripheral surfaces (an upper surface, a lower surface and side surfaces) of the core 106 in the separation region 153 are exposed (fifth step). This process is realized by etching with etchant for removing only InP. In the separation region 153, the upper surface of the fifth semiconductor layer 110 is exposed, and space 131 is formed around the core 106.

Then, a semi-insulating compound semiconductor is re-grown on the upper surface of the layers exposed at this time, and a re-growth layer 126 is formed as shown in FIG. 2J. In the first element region 151, the re-growth layer 126, at first, is formed on the exposed side surfaces of the first active layer 103a and a part of the first semiconductor layer 102a in the thickness direction that are part of the ridge and the exposed upper surfaces of the first semiconductor layer 102a. Further, in the second element region 152, the re-growth layer 126 is formed on the exposed side surfaces of the second active layer 103b and a part of the third semiconductor layer 102b in the thickness direction that are part of the ridge and the exposed upper surfaces of the third semiconductor layer 102b.

Further, the re-growth layer 126 is formed on the fifth semiconductor layer 110 exposed in the separation region 153 and on the core 106. Here, in the separation region 153, the re-growth layer 126 is formed on the fifth semiconductor layer 110 to be in a state of reaching the lower surface of the core 106. Further, the re-growth layer 126 is formed so as to bury the space between the core 106 and the semiconductor layer 105c.

Subsequently, a semi-insulating compound semiconductor is re-grown, as shown in FIG. 2K, thereby a first buried layer 108a, a second buried layer 108b, and a cladding 107 are formed (sixth and seventh steps). The optical waveguide 143 is configured by the core 106 and the cladding 107 that buries the core 106. Here, the space 131 is formed around the core 106 by removing the second conductivity type layer 104c and the first conductivity type layer 102c of the separation region 153, then subsequently, the first buried layer 108a, the second buried layer 108b and the cladding 107 are formed. Therefore, in the butt joint part between the first active layer 103a and the core 106 and the butt joint part between the second active layer 103b and the core 106, no problem occurs due to an optical axis deviation between them.

In this example, the sixth step and the seventh step are simultaneously performed, and the first buried layer 108a, the second buried layer 108b, and the cladding 107 are configured by the same compound semiconductor and are continuously and integrally formed in the waveguide direction. Here, by confirming that the cladding 107 is formed lower than the first buried layer 108a and the second buried layer 108b, it can be confirmed that the second conductivity type layer 104c of the separation region 153 has been removed.

The semi-insulating compound semiconductor to be re-grown, described above, can include Fe-doped InP (reference 1, reference 2). In this case, InP doped with Fe is grown while chlorine-based gas is added. For example, the crystal growth temperature is set to 600° C., and InP doped with Fe is grown while CH₃Cl is added. The doping amount of Fe can be 5E15 [cm⁻³]. Adding CH₃Cl gas promotes the growth of the [001] plane.

Next, as shown in FIG. 2L, a first p-electrode 111a which is ohmic-connected to the sixth semiconductor layer 105a of the first optical element 141 is formed, and a first n-electrode 112a which is ohmic-connected to the upper surface of the first semiconductor layer 102a of the first optical element 141 is formed. Similarly, as shown in FIG. 2M, a second p-electrode 111b which is ohmic-connected to the seventh semiconductor layer 105b of the second optical element 142 is formed, and a second n-electrode 112b which is ohmic-connected to the upper surface of the third semiconductor layer 102b is formed.

For formation of the first n-electrode 112a, the first buried layer 108a on the first semiconductor layer 102a in a corresponding place is removed, and the upper surface of the first semiconductor layer 102a is exposed. The first semiconductor layer 102a of a place to which the first n-electrode 112a contacts functions as a contact layer. Similarly, for formation of the second n-electrode 112b, the second buried layer 108b on the third semiconductor layer 102b in a corresponding place is removed, and the upper surface of the third semiconductor layer 102b is exposed. The third semiconductor layer 102b of a place to which the second n-electrode 112b contacts functions as a contact layer.

Here, while the first buried layer 108a, the second buried layer 108b, and the cladding 107 are formed by re-growth (buried growth), as described with reference to FIGS. 2J and 2K, with changing the crystal growth temperature in the burying step, the growing plane orientation can be controlled (reference 3). Further, in the growth of the first buried layer 108a, the second buried layer 108b, and the cladding 107, with adding carbon tetrachloride gas at the time of crystal growth, growth depending only on a specific plane orientation can be realized (reference 4).

In the semiconductor device produced by the production method described above, an electric resistance between the first p-electrode 111a of the first optical element 141 to be a semiconductor laser and the second p-electrode 111b of the second optical element 142 to be an EA optical modulator is 100 kΩ or more. Further, an electric resistance between the first n-electrode 112a of the first optical element 141 and the second n-electrode 112b of the second optical element 142 is also 100 kΩ or more. Compared with the electric resistance between the respective p-electrodes between the two optical elements in the conventional semiconductor device, a remarkable improvement can be realized. When a differential modulation signal is applied to the second optical element 142 serving as an EA optical modulator by using a semiconductor device actually produced to operate, the stable operation of the first optical element 141 serving as a semiconductor laser and the clear waveform opening of the second optical element 142 were confirmed by reflecting the above-mentioned high electric resistance.

By the way, in the above description, although showing the sample in which the first active layer 103a, the second active layer 103b, and the core 106 include InGaAsP, it is not limited thereto, and the first active layer 103a and the second active layer 103b can include InGaAlAs, InGaAs, or the like.

As described above, according to embodiments of the present invention, since the first optical element and the second optical element are formed on the substrate including the semi-insulating compound semiconductor and the cladding of the optical waveguide connecting them includes the semi-insulating compound semiconductor, the electric separation between the two optical elements can be realized without causing waveguide loss between the two optical elements.

According to embodiments of the present invention, in the semiconductor device in which optical elements are monolithically integrated, differential modulation driving of the optical elements can be realized. This effect improves the S/N ratio of the optical signal because the modulation amplitude voltage can be reduced by half and the common mode noise can be reduced (reference 5).

Note that it is clear that the present invention is not limited to the embodiments described above and, within the technical concept of the present invention, many modifications and combinations can be implemented by those skilled in the art.

### REFERENCES

Reference 1: M. Uchida et al., “Semi-insulating InP single crystal”, Journal of the Japanese Association for Crystal Growth, vol. 28, No. 1, pp. 37-44, 2001.
Reference 2: H. Yoshinaga et al., “Iron (Fe) concentration dependence of photoluminescence spectra in InP”, 1993 (5th) International Conference on Indium Phosphide and Related Materials, 4863850, pp. 317-320, 1993.
Reference 3: N. Nordell et al., “MOVPE growth of InP around reactive 10n etched mesas”, Journal of Crystal Growth, vol. 114, pp. 92-98, 1991.
Reference 4: N. Nordell et al., “Influence of MOVPE growth condition and CCl4 addition on InP crystal shapes”, Journal of Crystal Growth, vol. 125, pp. 597-611, 1992.
Reference 5: W. Kobayashi et al., “Design and Fabrication of Wide Wavelength Range 25.8-Gb/S, 1.3-μM, Push-Pull-Driven DMLs”, Journal of Lightwave Technology, vol. 32, No. 1, PP. 3-9, 2014.

### REFERENCE SIGNS LIST

101 Substrate
102a First semiconductor layer
102b Third semiconductor layer
103a First active layer
103b Second active layer
104a Second semiconductor layer
104b Fourth semiconductor layer
105a Sixth semiconductor layer
105b Seventh semiconductor layer
106 Core
107 Cladding
108a First buried layer
108b Second buried layer
110 Fifth semiconductor layer
141 First optical element
142 Second optical element
143 Optical waveguide
151 First element region
152 Second element region
153 Separation region

1.-7. (canceled)

8. A semiconductor device comprising:
a substrate comprising a first semi-insulating compound semiconductor,
a waveguide type first optical element disposed in a first element region of the substrate, wherein the waveguide type first optical element comprises:
a first semiconductor layer disposed on the substrate and comprising a first compound semiconductor of a first conductivity type;
a first active layer disposed on the first semiconductor layer and comprising a second compound semiconductor; and
a second semiconductor layer disposed on the first active layer and comprising a third compound semiconductor of a second conductivity type;
a waveguide type second optical element disposed in a second element region of the substrate, wherein the waveguide type second optical element comprises:
a third semiconductor layer disposed on the substrate and comprising the first compound semiconductor of the first conductivity type;
a second active layer disposed on the third semiconductor layer and comprising the second compound semiconductor; and
a fourth semiconductor layer disposed on the second active layer and comprising the third compound semiconductor of the second conductivity type; and
an optical waveguide disposed in a separation region between the first element region and the second element region of the substrate, wherein the optical waveguide is configured to optically connect the waveguide type first optical element and the waveguide type second optical element, and wherein the optical waveguide comprises:
a cladding disposed on the substrate and comprising a second semi-insulating compound semiconductor; and
a core buried in the cladding and comprising a fourth compound semiconductor.

9. The semiconductor device according to claim 8, wherein the first active layer, the core, and the second active layer are arranged such that lower surfaces thereof are at a same height.

10. The semiconductor device according to claim 9, further comprising:
a first buried layer disposed so as to bury a waveguide direction side of the waveguide type first optical element, the first buried layer comprising a third semi-insulating compound semiconductor; and
a second buried layer disposed so as to bury the waveguide direction side of the waveguide type second optical element, the second buried layer comprising a fourth semi-insulating compound semiconductor.

11. The semiconductor device according to claim 10, wherein an upper surface of the cladding of the optical waveguide is disposed lower than upper surfaces of the first buried layer and the second buried layer.

12. The semiconductor device according to claim 11, wherein:
the second semi-insulating compound semiconductor of the cladding, the third semi-insulating compound semiconductor of the first buried layer, and the fourth semi-insulating compound semiconductor of the second buried layer comprise the same semi-insulating compound semiconductor; and
the first buried layer, the second buried layer, and the cladding are continuously and integrally disposed in a waveguide direction.

13. The semiconductor device according to claim 8, further comprising:
a first buried layer disposed so as to bury a waveguide direction side of the waveguide type first optical element, the first buried layer comprising a third semi-insulating compound semiconductor; and
a second buried layer disposed so as to bury the waveguide direction side of the waveguide type second optical element, the second buried layer comprising a fourth semi-insulating compound semiconductor.

14. The semiconductor device according to claim 13, wherein an upper surface of the cladding of the optical waveguide is disposed lower than upper surfaces of the first buried layer and the second buried layer.

15. The semiconductor device according to claim 13, wherein:
the second semi-insulating compound semiconductor of the cladding, the third semi-insulating compound semiconductor of the first buried layer, and the fourth semi-insulating compound semiconductor of the second buried layer comprise the same semi-insulating compound semiconductor; and
the first buried layer, the second buried layer, and the cladding are continuously and integrally disposed in a waveguide direction.

16. A method of manufacturing a semiconductor device comprising a waveguide type first optical element disposed in a first element region of a substrate, a waveguide type second optical element disposed in a second element region of the substrate, and an optical waveguide disposed in a separation region between the first element region and the second element region of the substrate for optically connecting the waveguide type first optical element and the waveguide type second optical element, the method comprising:
forming a first conductivity type layer on the substrate, the substrate comprising a first semi-insulating compound semiconductor, and the first conductivity type layer comprising a first compound semiconductor of a first conductivity type;
forming a first active layer on the first conductivity type layer in the first element region of the substrate, the first active layer comprising a second compound semiconductor;
forming a second active layer on the first conductivity type layer in the second element region of the substrate, the second active layer comprising a third compound semiconductor;
forming a core layer on the first conductivity type layer in the separation region, wherein the core layer comprises a fourth compound semiconductor,
forming a second conductivity type layer on the first active layer, the second active layer, and the core layer, wherein the second conductivity type layer comprises a fifth compound semiconductor of a second conductivity type;
etching the second conductivity type layer, the first active layer, the second active layer, the core layer, and the first conductivity type layer so as to penetrate in a thickness direction;
forming the waveguide type first optical element in the first element region of the substrate, the waveguide type first optical element comprising:
a first semiconductor layer comprising the first conductivity type layer comprising the first compound semiconductor of the first conductivity type;
the first active layer on the first semiconductor layer, the first active layer comprising the second compound semiconductor; and
a second semiconductor layer on the first active layer, the second semiconductor layer comprising the second conductivity type layer comprising the fifth compound semiconductor of the second conductivity type;
forming the waveguide type second optical element in the second element region of the substrate, the waveguide type second optical element comprising:
a third semiconductor layer comprising the first conductivity type layer comprising the first compound semiconductor of the first conductivity type;
the second active layer on the third semiconductor layer, the second active layer comprising the third compound semiconductor; and
a fourth semiconductor layer on the second active layer in the second element region, the fourth semiconductor layer comprising the second conductivity type layer comprising the fifth compound semiconductor of the second conductivity type;
forming a core in the separation region, the core comprising a sixth compound semiconductor;
removing the second conductivity type layer and the first conductivity type layer in the separation region; and
forming a cladding that buries the core in the separation region to form the optical waveguide, the cladding comprising a second semi-insulating compound semiconductor.

17. The method according to claim 16, further comprising:
forming a first buried layer comprising a third semi-insulating compound semiconductor burying a waveguide direction side of the waveguide type first optical element; and
forming a second buried layer comprising a fourth semi-insulating compound semiconductor burying the waveguide direction side of the waveguide type second optical element.

18. The method according to claim 17, wherein forming the cladding, forming the first buried layer, and forming the second buried layer are performed simultaneously.

19. The method according to claim 17, wherein the second semi-insulating compound semiconductor of the cladding, the third semi-insulating compound semiconductor of the first buried layer, and the fourth semi-insulating compound semiconductor of the second buried layer comprise the same semi-insulating compound semiconductor.

20. The method according to claim 17, wherein the first buried layer, the second buried layer, and the cladding are continuously and integrally formed in a waveguide direction.

21. The method according to claim 17, wherein an upper surface of the optical waveguide is disposed lower than upper surfaces of the first buried layer and the second buried layer.

22. The method according to claim 16, wherein the method further comprises, prior to forming the first conductivity type layer on the substrate, forming a fifth semiconductor layer on the substrate, wherein the fifth semiconductor layer comprises a third semi-insulating compound semiconductor, and wherein the first conductivity type layer is formed on the fifth semiconductor layer.
